(19) United States
(12) Patent Application Publication
(10) Pub. No.: US 2025/0140770 A1
(43) Pub. Date: May 1, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Che-Yu LEE, Taichung City (TW); Chi-Ching HO, Taichung City (TW); Chao-Chiang PU, Taichung City (TW); Yi-Min FU, Taichung City (TW); Po-Yuan SU, Taichung City (TW)

(73) Assignee: SILICONWARE PRECISION INDUSTRIES CO., LTD., Taichung City (TW)

(21) Appl. No.: 18/618,586

(22) Filed: Mar. 27, 2024

(30) Foreign Application Priority Data
Oct. 31, 2023 (TW) 112141827

(51) Int. Cl. H01L 25/18; H01L 23/00; H01L 23/367; H01L 23/498; H01L 25/00

(52) U.S. Cl. CPC H01L 25/18; H01L 23/367; H01L 23/49838; H01L 24/16; H01L 24/32; H01L 24/73; H01L 25/50; H01L 2224/16238; H01L 2224/32238; H01L 2224/73204; H01L 2924/15153

(57) ABSTRACT

An electronic package and a manufacturing method thereof are provided, in which a photonic integrated circuit chip and an electronic integrated circuit chip are disposed on opposite sides of an interposer respectively, and the photonic integrated circuit chip and the electronic integrated circuit chip can accomplish signal connection with each other via a plurality of conductive vias in the interposer directly, thereby reducing the power consumption and transmission delay of the signals transmitted between the circuits.

### BACKGROUND

### 1. Technical Field

The present disclosure relates to an electronic packaging technology, and more particularly, to an electronic package integrating photonic integrated circuit component and a manufacturing method thereof.

### 2. Description of Related Art

The traffic of data processing centers (data centers) has increased in response to the increasingly important and widespread applications of high performance computing (HPC) technology in today's world, such as the development of medical technology, the development of cancer drugs, the automatic sensing and detection computation of self-driving vehicles, etc. As a result, silicon photonic solutions that combine various advanced packaging technologies have been developed correspondingly in order to solve the traffic of data centers.

Current internal optical communications within a data center mainly rely on pluggable devices as the interface for optical fiber connections to achieve photoelectric or electro-optical conversion between the transmitting end and the receiving end. In the internal architecture of the data center, all switches, routers and nodes basically need to be installed with pluggable devices. For large data centers, the number of pluggable devices required to be deployed is also very large, which also brings a heavy burden and increases transmission delay and power consumption. More importantly, if a 1.6 Tb/s, 3.2 Tb/s, or even higher transmission rate is required to be achieved in the future, the pluggable devices will also be subject to performance limitations.

To solve this problem, the industry has developed co-packaged optics (CPO) technology, which is an innovative method of integrating optical components and electronic components in the same package. As shown in FIG. 1, a photonic integrated circuit (PIC) chip 11 of a digital signal processor (DSP) and an electronic integrated circuit (EIC) chip 12 are packaged together on a substrate 13 to form a package module 1a, and the package module 1a is disposed on a motherboard 14. This integration approach is expected to overcome the challenges of pluggable devices and bring superior performance to high-speed data transmission.

However, the aforementioned co-packaged optical structure still has unsolved problems such as insufficient transmission speed (signal transmission between PIC/DSP and EIC must still be transmitted via the circuit layer on the same side of the substrate) and high heat generated by signal processing. Therefore, how to overcome the above-mentioned problems of the prior art has become an urgent issue to be solved.

### SUMMARY

In view of the various shortcomings of the prior art, the present disclosure provides an electronic package, which comprises: an interposer having a first surface, a second surface opposing the first surface, and a plurality of conductive vias; a photonic integrated circuit chip disposed on the first surface of the interposer and electrically connected to the plurality of conductive vias; and an electronic integrated circuit chip disposed on the second surface of the interposer and electrically connected to the plurality of conductive vias.

The present disclosure also provides a method of manufacturing an electronic package, the method comprises: providing a photonic integrated circuit chip, an electronic integrated circuit chip, and an interposer, wherein the interposer has a first surface, a second surface opposing the first surface, and a plurality of conductive vias; disposing the photonic integrated circuit chip onto the first surface of the interposer, and electrically connecting the photonic integrated circuit chip to the plurality of conductive vias; and disposing the electronic integrated circuit chip onto the second surface of the interposer, and electrically connecting the electronic integrated circuit chip to the plurality of conductive vias.

In the aforementioned electronic package and method, the photonic integrated circuit chip has a first active surface and a first inactive surface opposing the first active surface, the first active surface has a plurality of first connecting pads and at least one connecting portion, and a plurality of first conductive bumps are disposed on the plurality of first connecting pads.

In the aforementioned electronic package and method, the electronic integrated circuit chip has a second active surface and a second inactive surface opposing the second active surface, the second active surface has a plurality of second connecting pads, and a plurality of second conductive bumps are disposed on the plurality of second connecting pads.

In the aforementioned electronic package and method, the first surface of the interposer has a first circuit structure being electrically connected to the conductive vias, and/or the second surface of the interposer has a second circuit structure being electrically connected to the conductive vias.

In the aforementioned electronic package and method, the first surface of the interposer and/or the second surface of the interposer have a heat dissipating layer formed thereon.

In the aforementioned electronic package and method, the present disclosure further comprises disposing a plurality of conductive components on the second surface of the interposer for bonding onto a substrate.

In the aforementioned electronic package and method, the substrate has a recess, and the recess accommodates the electronic integrated circuit chip disposed on the second surface of the interposer.

As can be understood from the above, in the electronic package and the manufacturing method thereof of the present disclosure, the photonic integrated circuit chip and the electronic integrated circuit chip may accomplish signal interconnection with each other via the plurality of conductive vias of the interposer directly. Further, the distance between the photonic integrated circuit chip and the electronic integrated circuit chip is relatively close, so that the power consumption and transmission delay of the signals transmitted between the circuits can be reduced effectively, and the performance of raising the signal transmission rate can be reached successfully. In addition, since the heat dissipating layer is formed on the surface of the interposer, the heat of the chips can be dissipated and the heat dissipation effect can be improved via the structural design of the entire metal and the material properties of the metal.

### BRIEF DESCRIPTION OF THE DRAWINGS

FIG. 1 is a schematic cross-sectional view of a conventional co-packaged optical structure.

FIG. 2A, FIG. 2B-1, FIG. 2C and FIG. 2D are schematic cross-sectional views illustrating a manufacturing method of an electronic package of the present disclosure.

FIG. 2B-2 is a schematic partial top view of FIG. 2A.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “above,” “below,” “under,” “first,” “second,” “third,” “a,” “one,” “two” and the like are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

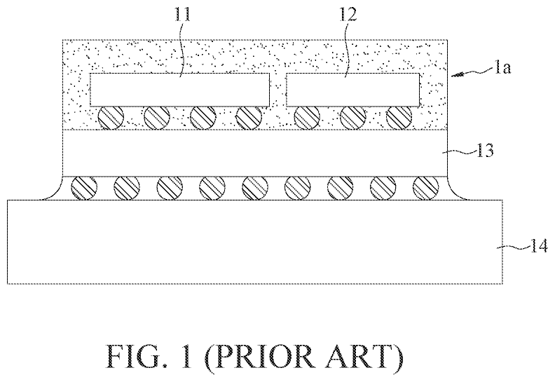

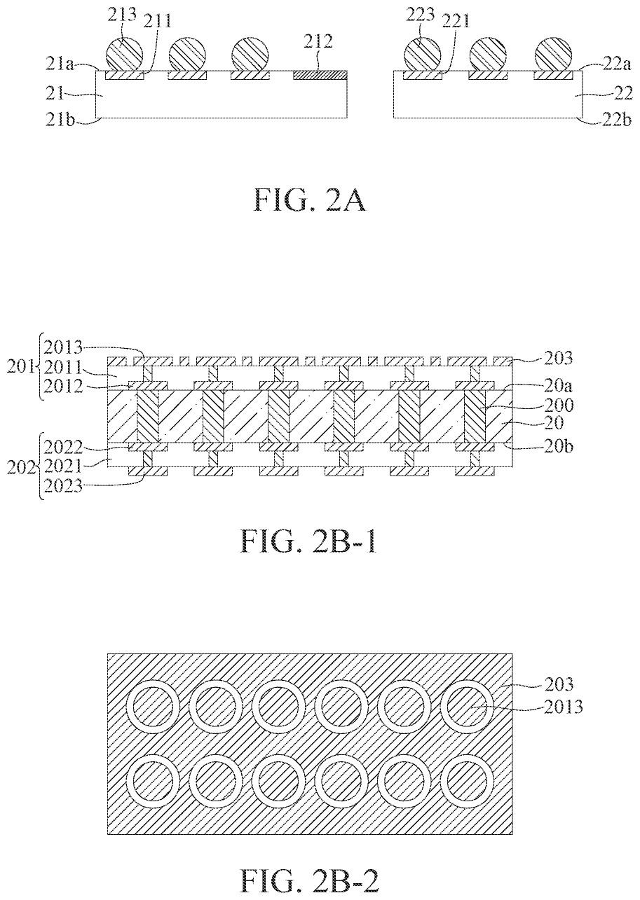

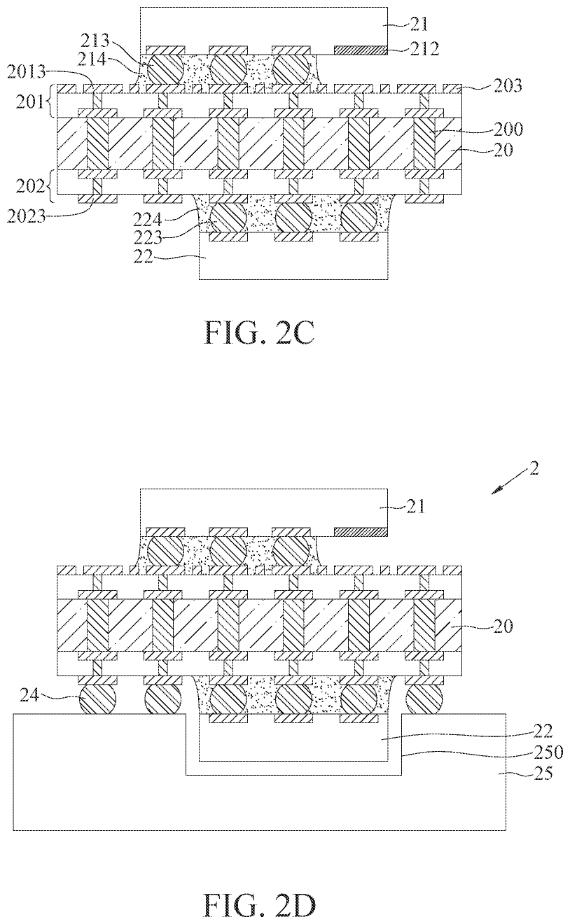

FIG. 2A, FIG. 2B-1, FIG. 2C and FIG. 2D are schematic cross-sectional views illustrating a manufacturing method of an electronic package 2 of the present disclosure.

As shown in FIG. 2A, at least one first electronic component and at least one second electronic component are provided. The first electronic component is, for example, a photonic integrated circuit (PIC) chip 21, which has a first active surface 21a and a first inactive surface 21b opposing the first active surface 21a, wherein the first active surface 21a has a plurality of first connecting pads 211 and at least one connecting portion 212, and a plurality of first conductive bumps 213 are disposed on the plurality of first connecting pads 211. The connecting portion 212 is, for example, an optical fiber connecting portion, and may be a contact for connecting an optical fiber or an optical fiber bus. The second electronic component is, for example, an electronic integrated circuit (EIC) chip 22, which has a second active surface 22a and a second inactive surface 22b opposing the second active surface 22a, wherein the second active surface 22a has a plurality of second connecting pads 221, and a plurality of second conductive bumps 223 are disposed on the plurality of second connecting pads 221. The first conductive bumps 213 and the second conductive bumps 223 are spherical conductive members such as solder balls, or cylindrical metal conductive members such as copper pillars, solder bumps, etc., or stud conductive members made by a wire bonding machine, but the present disclosure is not limited to as such.

As shown in FIG. 2B-1, an interposer 20 having a plurality of conductive vias 200 is provided, and the interposer 20 has a first surface 20a and a second surface 20b opposing the first surface 20a, such that the conductive vias 200 are in communication with the first surface 20a and the second surface 20b, wherein the interposer 20 is made of silicon or organic polymer material, preferably the interposer 20 is made of silicon.

In addition, a first circuit structure 201 can be formed on the first surface 20a of the interposer 20 and electrically connected to the conductive vias 200, and a second circuit structure 202 can be formed on the second surface 20b of the interposer 20 and electrically connected to the conductive vias 200.

The first circuit structure 201 comprises at least one (or a plurality of) first insulating layer 2011 and at least one (or a plurality of) first redistribution layer (RDL) 2012 formed on the first insulating layer 2011, and a plurality of first electrical contact pads 2013 are formed on the outermost first redistribution layer 2012. The second circuit structure 202 comprises at least one (or a plurality of) second insulating layer 2021 and at least one (or a plurality of) second redistribution layer 2022 formed on the second insulating layer 2021, and a plurality of second electrical contact pads 2023 are formed on the outermost second redistribution layer 2022. In an embodiment, the material for forming the first redistribution layer 2012 or the second redistribution layer 2022 is copper, and the material for forming the first insulating layer 2011 or the second insulating layer 2021 is dielectric material such as polybenzoxazole (PBO), polyimide (PI), prepreg (PP) and the like, or solder-resist material such as solder mask (e.g., green paint), graphite (e.g., ink), etc.

Referring to FIG. 2B-2, additionally, a heat dissipating layer 203 is formed on the first surface 20a of the interposer 20. In an embodiment, the heat dissipating layer 203 is formed on the outermost first insulating layer 2011 of the first circuit structure 201 and is adjacent to the plurality of first electrical contact pads 2013, and the heat dissipating layer 203 can be made of the same material as the plurality of first electrical contact pads 2013 and can be manufactured at the same time with the plurality of first electrical contact pads 2013, but the heat dissipating layer 203 is not in contact with or electrically connected to the plurality of first electrical contact pads 2013. Alternatively, the heat dissipating layer 203 can be formed on the second surface 20b of the interposer 20, or on both the first surface 20a and the second surface 20b of the interposer 20, such that the heat dissipating efficiency of the chip subsequently connected to the interposer 20 is improved via the arrangement of the heat dissipating layer 203.

It should be noted that in other embodiments, the making of the first circuit structure 201 can be omitted, and the plurality of first electrical contact pads 2013 being in contact with or connected electrically and directly to the plurality of conductive vias 200 and the heat dissipating layer 203 separated from the first electrical contact pads 2013 are formed on the first surface 20a of the interposer 20; and the making of the second circuit structure 202 can be also omitted, and the plurality of second electrical contact pads 2023 being in contact with or connected electrically and directly to the plurality of conductive vias 200 are formed on the second surface 20b of the interposer 20.

As shown in FIG. 2C, the photonic integrated circuit chip 21 is disposed on the first surface 20a of the interposer 20 and is electrically connected to the plurality of conductive vias 200, and the electronic integrated circuit chip 22 is disposed on the second surface 20b of the interposer 20 and is electrically connected to the plurality of conductive vias 200, such that the photonic integrated circuit chip 21 and the electronic integrated circuit chip 22 may achieve signal interconnection with each other via the plurality of conductive vias 200 of the interposer 20.

In an embodiment, the photonic integrated circuit chip 21 is connected to the plurality of first electrical contact pads 2013 via the plurality of first conductive bumps 213, and a first underfill 214 can be formed between the photonic integrated circuit chip 21 and the first circuit structure 201 to encapsulate the plurality of first conductive bumps 213. The electronic integrated circuit chip 22 is connected to the plurality of second electrical contact pads 2023 via the plurality of second conductive bumps 223, and a second underfill 224 can be formed between the electronic integrated circuit chip 22 and the second circuit structure 202 to encapsulate the plurality of second conductive bumps 223.

As shown in FIG. 2D, a plurality of conductive components 24 (such as copper pillars or solder balls) are placed on the second surface 20b of the interposer 20, i.e., the plurality of conductive components 24 can be disposed on the plurality of second electrical contact pads 2023 so as to be disposed on and connected to a substrate 25, thereby obtaining the electronic package 2 of the present disclosure.

In addition, a recess 250 can be formed on the substrate 25 for accommodating the electronic integrated circuit chip 22 disposed on the second surface 20b of the interposer 20, such that the height of the whole package can be reduced.

The present disclosure also provides an electronic package 2, which comprises: an interposer 20 having a first surface 20a, a second surface 20b opposing the first surface 20a, and a plurality of conductive vias 200; a photonic integrated circuit chip 21 disposed on the first surface 20a of the interposer 20 and electrically connected to the plurality of conductive vias 200; and an electronic integrated circuit chip 22 disposed on the second surface 20b of the interposer 20 and electrically connected to the plurality of conductive vias 200.

In an embodiment, the first surface 20a of the interposer 20 has a first circuit structure 201 being electrically connected to the conductive vias 200, and/or the second surface 20b of the interposer 20 has a second circuit structure 202 being electrically connected to the conductive vias 200.

In an embodiment, the photonic integrated circuit chip 21 has a first active surface 21a and a first inactive surface 21b opposing the first active surface 21a, wherein the first active surface 21a has a plurality of first connecting pads 211 and at least one connecting portion 212, and a plurality of first conductive bumps 213 are disposed on the plurality of first connecting pads 211, and the connecting portion 212 may be a contact for connecting an optical fiber or an optical fiber bus. The electronic integrated circuit chip 22 has a second active surface 22a and a second inactive surface 22b opposing the second active surface 22a, wherein the second active surface 22a has a plurality of second connecting pads 221, and a plurality of second conductive bumps 223 are disposed on the plurality of second connecting pads 221.

In an embodiment, a heat dissipating layer 203 is formed on the first surface 20a of the interposer 20, so that the heat of the chips can be dissipated and the heat dissipation effect can be improved.

In an embodiment, a plurality of conductive components 24 are disposed on the second surface 20b of the interposer 20, and the plurality of conductive components 24 are bonded to a substrate 25.

In summary, in the electronic package and the manufacturing method thereof of the present disclosure, the photonic integrated circuit chip 21 and the electronic integrated circuit chip 22 may accomplish signal interconnection with each other via the interposer 20 (the plurality of conductive vias 200) directly. Further, the distance between the photonic integrated circuit chip 21 and the electronic integrated circuit chip 22 is relatively close, so that the power consumption and transmission delay of the signals transmitted between the circuits can be reduced effectively, and the performance of raising the signal transmission rate can be reached successfully. In addition, since the structure of the heat dissipating layer 203 is formed on the surface of the interposer 20, the heat of the chips can be dissipated and the heat dissipation effect can be improved via the structural design of the entire metal and the material properties of the metal.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
an interposer having a first surface, a second surface opposing the first surface, and a plurality of conductive vias;
a photonic integrated circuit chip disposed on the first surface of the interposer and electrically connected to the plurality of conductive vias; and
an electronic integrated circuit chip disposed on the second surface of the interposer and electrically connected to the plurality of conductive vias.

2. The electronic package of claim 1, wherein the photonic integrated circuit chip has a first active surface and a first inactive surface opposing the first active surface, the first active surface has a plurality of first connecting pads and at least one connecting portion, and a plurality of first conductive bumps are disposed on the plurality of first connecting pads.

3. The electronic package of claim 1, wherein the electronic integrated circuit chip has a second active surface and a second inactive surface opposing the second active surface, the second active surface has a plurality of second connecting pads, and a plurality of second conductive bumps are disposed on the plurality of second connecting pads.

4. The electronic package of claim 1, wherein the first surface of the interposer has a first circuit structure being electrically connected to the conductive vias, and/or the second surface of the interposer has a second circuit structure being electrically connected to the conductive vias.

5. The electronic package of claim 1, wherein the first surface of the interposer and/or the second surface of the interposer have a heat dissipating layer formed thereon.

6. The electronic package of claim 1, further comprising a plurality of conductive components disposed on the second surface of the interposer, and a substrate bonded to the plurality of conductive components.

7. The electronic package of claim 6, wherein the substrate has a recess, and the recess accommodates the electronic integrated circuit chip disposed on the second surface of the interposer.

8. A method of manufacturing an electronic package, comprising:
providing a photonic integrated circuit chip, an electronic integrated circuit chip, and an interposer, wherein the interposer has a first surface, a second surface opposing the first surface, and a plurality of conductive vias;
disposing the photonic integrated circuit chip onto the first surface of the interposer, and electrically connecting the photonic integrated circuit chip to the plurality of conductive vias; and
disposing the electronic integrated circuit chip onto the second surface of the interposer, and electrically connecting the electronic integrated circuit chip to the plurality of conductive vias.

9. The method of claim 8, wherein the photonic integrated circuit chip has a first active surface and a first inactive surface opposing the first active surface, the first active surface has a plurality of first connecting pads and at least one connecting portion, and a plurality of first conductive bumps are disposed on the plurality of first connecting pads.

10. The method of claim 8, wherein the electronic integrated circuit chip has a second active surface and a second inactive surface opposing the second active surface, the second active surface has a plurality of second connecting pads, and a plurality of second conductive bumps are disposed on the plurality of second connecting pads.

11. The method of claim 8, wherein the first surface of the interposer has a first circuit structure being electrically connected to the conductive vias, and/or the second surface of the interposer has a second circuit structure being electrically connected to the conductive vias.

12. The method of claim 8, wherein the first surface of the interposer and/or the second surface of the interposer have a heat dissipating layer formed thereon.

13. The method of claim 8, further comprising disposing a plurality of conductive components on the second surface of the interposer for bonding onto a substrate.

14. The method of claim 13, wherein the substrate has a recess, and the recess accommodates the electronic integrated circuit chip disposed on the second surface of the interposer.
